(19) United States
(12) Patent Application Publication
(10) Pub. No.: US 2009/0244206 A1
(43) Pub. Date: Oct. 1, 2009

(54) PIEZOELECTRIC ELEMENT AND ITS MANUFACTURING METHOD, PIEZOELECTRIC ACTUATOR, AND LIQUID JET HEAD

(75) Inventor: Masao NAKAYAMA, Shiojiri (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/414,751

(22) Filed: Mar. 31, 2009

(30) Foreign Application Priority Data
Apr. 1, 2008 (JP) 2008-094619

(51) Int. Cl. B41J 2/045; H01L 41/04; H01L 41/24

(52) U.S. Cl. 347/68; 310/367; 29/25.35

(57) ABSTRACT

A piezoelectric element includes: a substrate; a lower electrode formed above the substrate; a piezoelectric layer formed above the lower electrode; and an upper electrode formed above and at least in a portion of the piezoelectric layer, wherein the piezoelectric layer has a first portion formed between the lower electrode and the upper electrode and a second portion formed outside and continuous with the first portion, the second portion covering at least a portion of the lower electrode, and having a film thickness that is thinner than a film thickness of the first portion.

This application claims a priority to Japanese Patent Application No. 2008-094619 filed on Apr. 1, 2008 which is hereby expressly incorporated by reference herein in its entirety.

### BACKGROUND

1. Technical Field

The present invention relates to piezoelectric elements and methods for manufacturing the same, piezoelectric actuators, and liquid jet heads.

2. Related Art

At present, ink jet recording apparatuses are placed in practical use as high-definition and high-speed printing methods. As liquid jet heads to be mounted on ink jet recording apparatuses, a method that uses piezoelectric elements having a structure in which a piezoelectric layer is sandwiched by a lower electrode and an upper electrode is useful. Lead zirconate titanate (PZT) is known as a representative material for piezoelectric layers (see Japanese Laid-open Patent Application JP-A-2005-119199).

Dry etching is generally used for processing piezoelectric layers. In order to achieve a large amount of displacement in a piezoelectric layer, a taper angle, in other words, an angle defined between a lower electrode and the side surface of the piezoelectric layer, may preferably be 50° or greater. However, in the step of etching a piezoelectric layer, the material of the lower electrode may be deposited on the side surface of the piezoelectric layer if a large taper angle is made, which may cause leakage current. Also, the interface between the piezoelectric layer and the lower electrode may be damaged by active gas such as chlorine gas that is used at the time of dry etching. The increase in leakage current and the damage on the interface between the piezoelectric layer and the lower electrode would lead to deterioration of the characteristics of piezoelectric elements.

### SUMMARY

In accordance with an advantage of some aspects of the invention, piezoelectric elements with controlled characteristic deterioration and methods for manufacturing the same can be provided. Also, in accordance with another advantage of some aspects of the invention, piezoelectric actuators and liquid jet heads using the piezoelectric elements described above can be provided.

A piezoelectric element in accordance with an embodiment of the invention includes: a substrate; a lower electrode formed above the substrate; a piezoelectric layer formed above the lower electrode; and an upper electrode formed above and at least in a portion of the piezoelectric layer, wherein the piezoelectric layer has a first portion formed between the lower electrode and the upper electrode, and a second portion formed outside and continuous with the first portion, wherein the second portion covers at least a portion of the lower electrode, and has a film thickness that is thinner than the film thickness of the first portion.

According to the piezoelectric element in accordance with the embodiment described above, the piezoelectric layer has the first portion formed between the lower electrode and the upper electrode, and the second portion formed outside and continuous with the first portion. The second portion covers at least a portion of the lower electrode, and is thinner than the film thickness of the first portion, such that deterioration of the characteristics of the piezoelectric element can be suppressed without obstructing deformation of the first portion and displacement of the vibration plate.

In the description of the invention, the term “above” is used, for example, as in a statement “a specific component (hereinafter called ‘B’) is formed ‘above’ another specific component (hereinafter called ‘A’).” In such a case, the term “above” is used in the description of the invention, while assuming to include the case where the component B is formed directly on the component A and the case where the component B is formed over the component A through another component provided on the component A. Similarly, the term “below” is used, while assuming to include the case where the component B is formed directly under in contact with the component A and the case where the component B is formed under the component A through another component.

In the piezoelectric element in accordance with an aspect of the invention, the second portion may have a tapered shape in which the film thickness becomes thinner in a direction away from the first portion.

In the piezoelectric element in accordance with an aspect of the invention, the second portion may have a maximum film thickness that is 1/10 or less of the film thickness of the first portion.

In the piezoelectric element in accordance with an aspect of the invention, the lower electrode may be a common electrode, and at least a portion of the lower electrode may be exposed.

In the piezoelectric element in accordance with an aspect of the invention, the lower electrode may be a common electrode, and covered by the second portion.

A method for manufacturing a piezoelectric element in accordance with an embodiment of the invention includes the steps of: forming a lower electrode above a substrate; forming a piezoelectric layer above the lower electrode; forming an upper electrode above the piezoelectric layer; and patterning the piezoelectric layer and the upper electrode, wherein the step of patterning is conducted by dry etching in a manner that the piezoelectric layer has a first portion formed between the lower electrode and the upper electrode, and a second portion formed outside and continuous with the first portion, and the dry etching is stopped such that the second portion covers at least a portion of the lower electrode and the second portion is formed to have a film thickness thinner than the first portion.

A method for manufacturing a piezoelectric element in accordance with an embodiment of the invention includes the steps of: forming a lower electrode above a substrate; forming a piezoelectric layer above the lower electrode; forming an upper electrode above the piezoelectric layer; and patterning the piezoelectric layer and the upper electrode, wherein the step of patterning includes the step of forming, by dry etching with low ion rectilinear propagation, a first portion of the piezoelectric layer between the lower electrode and the upper electrode, and a deposit layer in at least a portion of a side surface of the first portion; removing the deposit layer and forming a second portion of the piezoelectric layer outside and continuous with the first portion by dry etching with high ion rectilinear propagation; and stopping the dry etching in a manner that the second portion covers at least a portion of the lower electrode and the second portion is formed to have a film thickness thinner than the first portion.

A piezoelectric actuator in accordance with an embodiment of the invention includes: a piezoelectric element in accordance with an aspect of the invention, and a vibration plate that is formed above the substrate and is deformed by the piezoelectric element.

A liquid jet head in accordance with an embodiment of the invention includes a piezoelectric actuator in accordance with an aspect of the invention, a pressure chamber formed in the substrate, and a nozzle plate that is formed below the substrate and has a nozzle aperture communicating with the pressure chamber.

### BRIEF DESCRIPTION OF THE DRAWINGS

FIG. 1 is a schematic cross-sectional view of a piezoelectric element in accordance with an embodiment of the invention.

FIG. 2 is a schematic cross-sectional view of a piezoelectric element in accordance with an embodiment of the invention.

FIG. 3 is a schematic cross-sectional view of a piezoelectric element in accordance with an embodiment of the invention.

FIG. 4 is a schematic cross-sectional view showing a step of a method for manufacturing a piezoelectric element in accordance with an embodiment of the invention.

FIG. 5 is a schematic cross-sectional view showing a step of the method for manufacturing a piezoelectric element in accordance with the embodiment of the invention.

FIG. 6 is a schematic cross-sectional view showing a step of the method for manufacturing a piezoelectric element in accordance with the embodiment of the invention.

FIG. 7 is a schematic cross-sectional view showing a step of a method for manufacturing a piezoelectric element in accordance with a modified example of the embodiment of the invention.

FIG. 8 is a schematic cross-sectional view showing a step of a method for manufacturing a piezoelectric element in accordance with a modified example of the embodiment of the invention.

FIG. 9 is an SEM observation result of a cross section of a piezoelectric element in accordance with an embodiment example of the invention.

FIG. 10 is an SEM observation result of a cross section of a piezoelectric element in accordance with a comparison example.

FIG. 11 is a graph showing measurement results of leakage current of the piezoelectric element of the embodiment example and the piezoelectric element of the comparison example.

FIG. 12 is a schematic cross-sectional view of a liquid jet head in accordance with an embodiment of the invention.

FIG. 13 schematically shows an exploded perspective view of a liquid jet head in accordance with an embodiment of the invention.

### DESCRIPTION OF EXEMPLARY EMBODIMENTS

Preferred embodiments of the invention are described below with reference to the accompanying drawings.

### 1. Piezoelectric Element

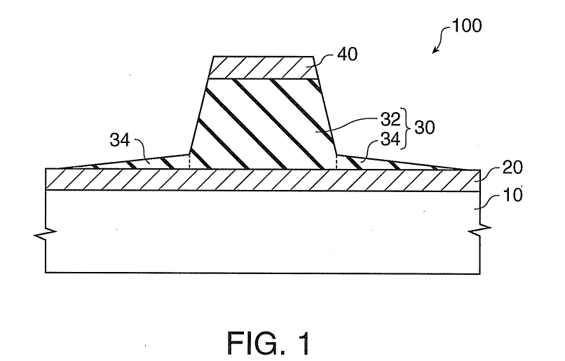

FIGS. 1-3 are schematic cross-sectional views of a piezoelectric element 100 in accordance with an embodiment of the invention.

The piezoelectric element 100 includes, as shown in FIG. 1, a substrate 10, a lower electrode 20, a piezoelectric layer 30 and an upper electrode 40. The piezoelectric layer 30 has a first portion 32 and a second portion 34.

As the material for the substrate 10, for example, conductive materials, semiconductor materials, or dielectric materials can be used, without any particular limitation. The substrate 10 may be formed from, for example, a (110) single crystal silicon substrate. For example, pressure chambers 12 (see FIG. 12) of an ink jet recording head to be described below may be formed in the substrate 10. The substrate 10 may also include, for example, a vibration plate 60 (see FIG. 12) and an adhesion layer such as a titanium oxide layer.

The lower electrode 20 is formed on the substrate 10. The lower electrode 20 is one of the electrodes for applying a voltage to the first portion 32 of the piezoelectric element 30. The lower electrode 20 may be formed from, for example, platinum, iridium, and oxides, such as, conductive oxide of the foregoing material, lanthanum nickel oxide (LNO) and the like. The lower electrode may be in a single layer of any one of the materials exemplified above, or may be in a laminate structure of layers of plural materials. The thickness of the lower electrode 20 may be, for example, 50 nm-300 nm.

The piezoelectric layer 30 is formed on the lower electrode 20. The piezoelectric layer 30 may be formed from a material having piezoelectric property. The piezoelectric layer 30 may be composed of, for example, perovskite type oxides. More concretely, the piezoelectric layer 30 may be formed from, for example, lead zirconate titanate (Pb (Zr, Ti) O₃: PZT) (hereafter referred to as PZT), lead zirconate titanate niobate (Pb (Zr, Ti, Nb) O₃: PZTN) or the like. The piezoelectric layer 30 has the first portion 32 and the second portion 34.

The first portion 32 is formed above the lower electrode 20. The first portion 32 is formed between the lower electrode 20 and the upper electrode 40, and can be driven by a voltage applied thereto.

The second portion 34 is formed outside the first portion 32 and continuous with the first portion 32. The second portion 34 may be formed, for example, protruding from the first portion 32. Also, the second portion 34 is formed in a manner to cover at least a portion of the lower electrode 20. As a result, deposition of the material composing the lower electrode 20 on the side surface of the first portion 32, which may cause leakage current, can be suppressed at the time of patterning the piezoelectric layer 30, as described below. Also, the second portion 34 can suppress damage to the interface between the first portion 32 and the lower electrode 20 which may be caused by active gas at the time of dry etching.

The second portion 34 is formed to have a film thickness thinner than the film thickness of the first portion 32. The second portion 34 may be in a tapered shape in which its film thickness becomes thinner in a direction extending away from the first portion 32. Accordingly, it is possible that the second portion 34 would not prevent deformation of the first portion 32 and displacement of the vibration plate 60 (see FIG. 12). For example, the maximum film thickness of the second portion 34, which is the film thickness thereof at a portion where the second portion 34 contacts the first portion 32, may preferably be 1/10 or less of the film thickness of the first portion 32. The film thickness of the second portion 34 at a portion where the second portion 34 contacts the first portion 32 may be, for example, 20 nm-100 nm.

The length of the second portion 34, in other words, the length from the portion where the second portion 34 contacts the first portion 32 to the tip of the second portion 34, may be, for example, 100 nm or greater, depending on the length of the first portion 32. The taper angle of the second portion 34, in other words, the angle defined between the sloped surface of the second portion 34 and the lower electrode 20 may be, for example, about 1°.

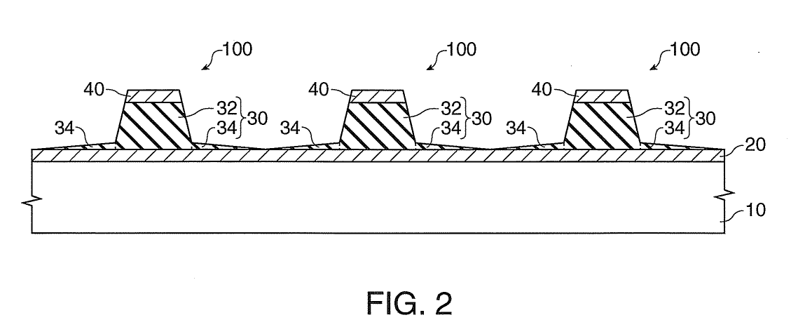

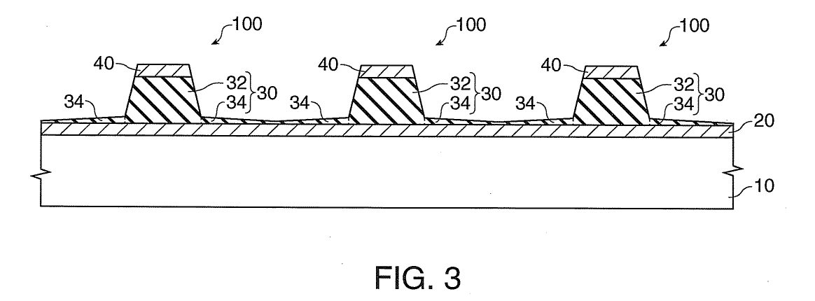

When the lower electrode 20 is a common electrode, the lower electrode may have an exposed region between adjacent ones of the first portions 32, as shown in FIG. 2. By this, it is possible that the second portion 34 would not prevent displacement of the vibration plate 60. Also, it is possible that the lower electrode 20 would be covered by the second portion 34, as shown in FIG. 3. The second portion 34 may cover the lower electrode 20, if its film thickness is thinly formed to the extent that displacement of the vibration plate 60 would not be prevented.

The upper electrode 40 is formed on the first portion 32. The upper electrode 40 pairs with the lower electrode 20 to function as the other electrode. The thickness of the upper electrode 40 may be, for example, 20 nm-200 nm. The upper electrode 40 may be formed from, for example, platinum, iridium, or conductive oxide of the foregoing material. The upper electrode 40 may be in a single layer of any one of the materials exemplified above, or in a laminate structure of layers of plural materials.

The piezoelectric element 100 may have, for example, the following characteristics.

The piezoelectric element 100 has the second portion 34 formed continuously with the first portion 32, outside the first portion 32 of the piezoelectric layer 30. As a consequence, the exposed portion of the lower electrode 20 and the side wall of the piezoelectric layer 30 are physically separated from each other by the second portion 34. Therefore, when the piezoelectric layer 30 is etched, the material composing the lower electrode 20, which would cause leakage current, can be prevented from depositing on the side surface of the first portion 32. Accordingly, the taper angle of the first portion 32 can be made larger. In other words, the piezoelectric element can be formed with good displacement characteristics. Also, by the second portion 34, the interface between the first portion 32 and the lower electrode 20 would not be exposed at the time of dry etching, such that damage to the interface can be suppressed. Therefore, the characteristics of the piezoelectric element 100 can be substantially prevented from being deteriorated.

According to the piezoelectric element 100, the second portion 34 of the piezoelectric layer 30 can have a film thickness thinner than the first portion 32 of the piezoelectric layer 30, and may be in tapered shape in which its thickness becomes thinner in a direction extending away from the first portion 32. As a result, the second portion 34 can suppress deterioration of the characteristics of the piezoelectric element 100 without preventing deformation of the first portion 32 and displacement of the vibration plate 60.

### 2. Method for Manufacturing Piezoelectric Element

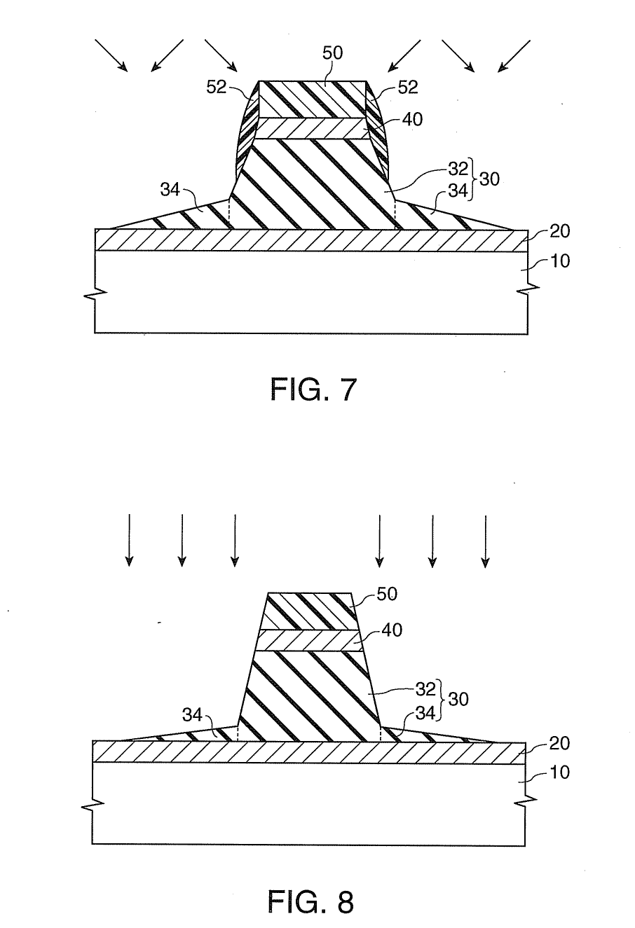

Next, a method for manufacturing a piezoelectric element 100 in accordance with an embodiment of the invention shall be described with reference to the accompanying drawings. FIGS. 4-6 are schematic cross-sectional views showing steps of a method for manufacturing a piezoelectric element 100 in accordance with an embodiment of the invention. FIGS. 7 and 8 are schematic cross-sectional views showing steps of a method for manufacturing a piezoelectric element 100 in accordance with modified examples of the embodiment of the invention.

As shown in FIG. 4, films of a lower electrode 20, a piezoelectric layer 30 and an upper electrode 40 are formed in this order on a substrate 10.

The films for the lower electrode 20 and the upper electrode 40 are formed by, for example, a sputter method, a plating method or a vapor deposition method.

The piezoelectric layer 30 may be formed by, for example, a sol-gel method, a CVD (Chemical Vapor Deposition) method, a MOD (metal organic deposition) method, a sputter method or a laser ablation method. When the piezoelectric layer 30 is formed from a material composed of PZT, for example, annealing at about 700° C. in an oxygen atmosphere may be conducted, whereby the piezoelectric layer 30 is crystallized.

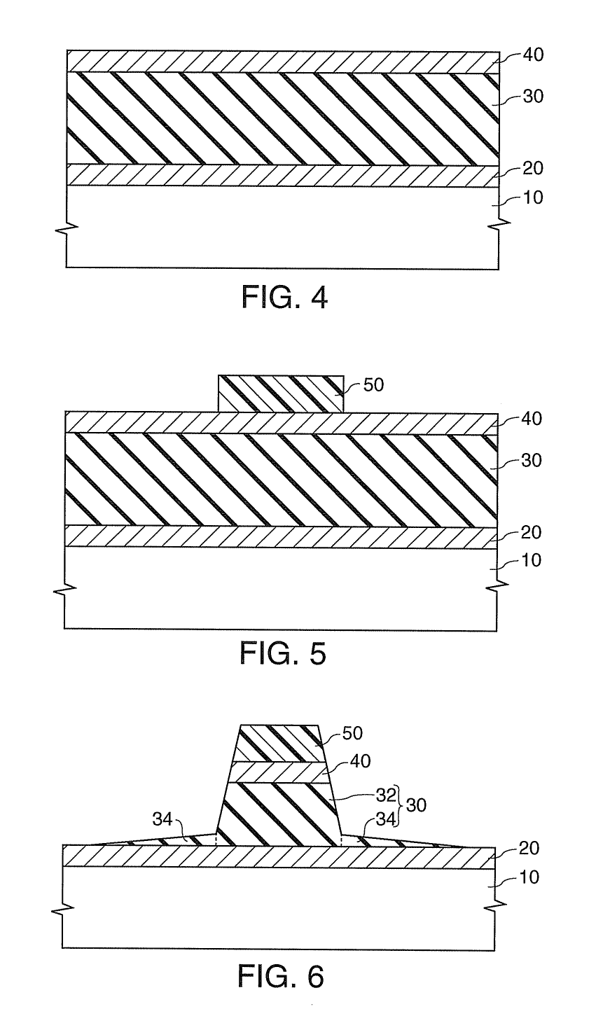

As shown in FIG. 5, a resist mask 50 is formed on the upper electrode 40. The resist mask 50 may be formed by a known method, and patterned. If oxygen is to be introduced in the step of patterning the upper electrode 40 and the piezoelectric layer 30 to be described below, a hard mask composed of, for example, titanium (Ti), lanthanum nickel oxide (LNO) or the like may preferably be used.

As shown in FIG. 6, the upper electrode 40 and the piezoelectric layer 30 are patterned. The patterning may be conducted by, for example, dry etching. The dry etching may be conducted with an etching apparatus that uses high density plasma, such as, for example, ICP (Inductively Coupled Plasma) at a pressure of 1.0 Pa or lower, whereby good patterning can be conducted. As an etching gas for etching the upper electrode 40, for example, a mixed gas of chlorine gas and argon gas may be used. As an etching gas for etching the piezoelectric layer 30, for example, a mixed gas of chlorine-group gas and fluorocarbon-group gas may be used. As the chlorine-group gas, for example, BCl₃ and Cl₂ may be enumerated. As the fluorocarbon-group gas, for example, CF₄ and C₂F₆ may be enumerated.

The first portion 32 of the piezoelectric layer 30 is formed by dry etching, and a tapered shape, having a film thickness that gradually thins in a direction extending away from the first portion 32, is formed outside the first portion 32 by the μ loading (micro-loading) effect. The μ loading effect is a phenomenon in which etching rate and shape change due to local differences in pattern density. By the μ loading effect, for example, the etching rate becomes lower in portions of higher pattern density, and the etching rate becomes higher in portions of coarse pattern density. By introducing oxygen at the time of dry etching, the μ loading effect can be enhanced.

By stopping the etching when the outside of the first portion 32 becomes to have a desired shape, whereby the second portion 34 is formed. For example, by stopping the etching when at least a portion of the lower electrode 20 is exposed, the second portion 34 can be formed. The second portion 34 can be formed in an arbitrary shape by adjusting the amount of over-etching.

As shown in FIG. 1, the resist mask 50 is removed. The resist mask 50 can be removed by a known method.

By the steps described above, the piezoelectric element 100 is manufactured.

As a modified example, the step of patterning the piezoelectric layer 30 described above may be replaced with the following step, to manufacture the piezoelectric element 100.

As shown in FIG. 7 the upper electrode 40 and the piezoelectric layer 30 are etched. The etching is conducted by dry etching with low ion rectilinear propagation. The dry etching may be conducted, using an etching apparatus with high density plasma, such as, for example, ICP (Inductively Coupled Plasma), at a pressure of about 2.0 Pa, whereby etching with low ion rectilinear propagation can be conducted. As the etching gas, for example, a mixed gas of chlorine-group gas and fluorocarbon-group gas may be used. As the rectilinear propagation of ions is low, deposit layers 52 composed of waste materials from etching of the piezoelectric layer 30 and polymers containing carbon and fluorocarbon are formed on the side surfaces of the resist mask 50 and the first portion 32. As the deposit layers 52 function as masks, the piezoelectric layer 30 is etched such that the taper angle of the first portion 32, in other words, the angle defined between the lower electrode 20 and the side surface of the first portion 32 is formed smaller than that to be formed when the rectilinear propagation of ions is high.

As shown in FIG. 8, dry etching with high ion rectilinear propagation is conducted. For example, by changing the etching condition with low ion rectilinear propagation described above to a condition with the pressure being 0.5 Pa or lower, etching with high ion rectilinear propagation can be conducted. By this etching, the deposit layers 52 are removed, the first portion 32 is formed, and the taper angle of the first portion becomes greater. Furthermore, a tapered section that becomes thinner in a direction extending away from the first portion 32 is formed outside the first portion 32.

When the outside of the first portion 32 is formed into a desired shape, the etching is stopped, whereby the second portion 34 is formed. For example, the etching may be stopped at the time when at least a portion of the lower electrode 20 is exposed, whereby the second portion 34 can be formed. The second portion 34 can be formed in any arbitrary shape by adjusting the amount of over-etching.

By the steps described above, the piezoelectric element 100 is manufactured.

The method for manufacturing the piezoelectric element 100 has, for example, the following characteristics.

According to the method for manufacturing a piezoelectric element 100, in the step of patterning the piezoelectric layer 30, the second portion 34 that is continuous with the first portion 32 can be formed outside the first portion 32. By this, deposition of the material composing the lower electrode 20 on the side surface of the first portion 32, which would cause leakage current, can be suppressed. Accordingly, with the piezoelectric element 100, deterioration of its characteristics can be suppressed.

In the piezoelectric element 100, the second portion 34 has a film thickness thinner than that of the first portion 32, and may be in a tapered shape in which its film thickness becomes thinner in a direction extending away from the first portion 32. By this, the second portion 34 can suppress deterioration of the characteristics of the piezoelectric element 100 without preventing deformation of the first portion 32 and displacement of the vibration plate 60.

### 3. Embodiment Example

Embodiment examples of the invention shall be described below, but the invention is not limited to these embodiment examples.

### 3.1. Method for Manufacturing Samples in Accordance with Embodiment Example

A sample of a piezoelectric element 100 in accordance with the embodiment example was obtained as follows.

On a silicon substrate was formed a lower electrode 20 composed of a laminate structure in which a platinum layer having a thickness of 100 nm and a iridium layer having a thickness of 20 nm were sequentially formed. The lower electrode 20 was formed by a sputter method.

A piezoelectric layer 30 composed of PZT having a thickness of 1.2 μm was formed on the lower electrode 20. The piezoelectric layer 30 was formed by a MOD (Metal Organic Deposition) method.

An upper electrode 40 composed of iridium having a thickness of 50 nm was formed on the piezoelectric layer 30. The upper electrode 40 was formed by a sputter method.

The upper electrode 40 and the piezoelectric layer 30 were etched by dry etching, whereby the upper electrode 40, the first portion 32 and the second portion 34 were formed. The dry etching of the piezoelectric layer 30 was conducted with an etching apparatus, using ICP (Inductively Coupled Plasma) at a pressure of 0.5 Pa or lower. As the etching gas, a mixed gas of BCl₃ and C₄F₈ was used. The second portion 34 of the piezoelectric layer 30 was formed into a specified shape by adjusting the amount of over-etching.

### 3.2. Method for Manufacturing Sample in Accordance with Comparison Example

A piezoelectric element of a comparison example is generally the same as the piezoelectric element 100 in accordance with the present embodiment example, except that the comparison example does not have a second portion 34. The piezoelectric element sample of the comparison example was formed in a manner that, in the step of etching a piezoelectric layer 30x, the amount of over-etching was increased more than that of the piezoelectric element 100 of the embodiment example so as not to leave a portion corresponding to the second portion 34 of the embodiment example. The other steps were conducted in a way similar to that of the piezoelectric element 100 of the embodiment example, whereby the piezoelectric element of the comparison example was manufactured.

Shape of Second Portion of Piezoelectric Layer

The piezoelectric element 100 of the embodiment example formed by the method described above was evaluated, using a scanning electron microscope (SEM).

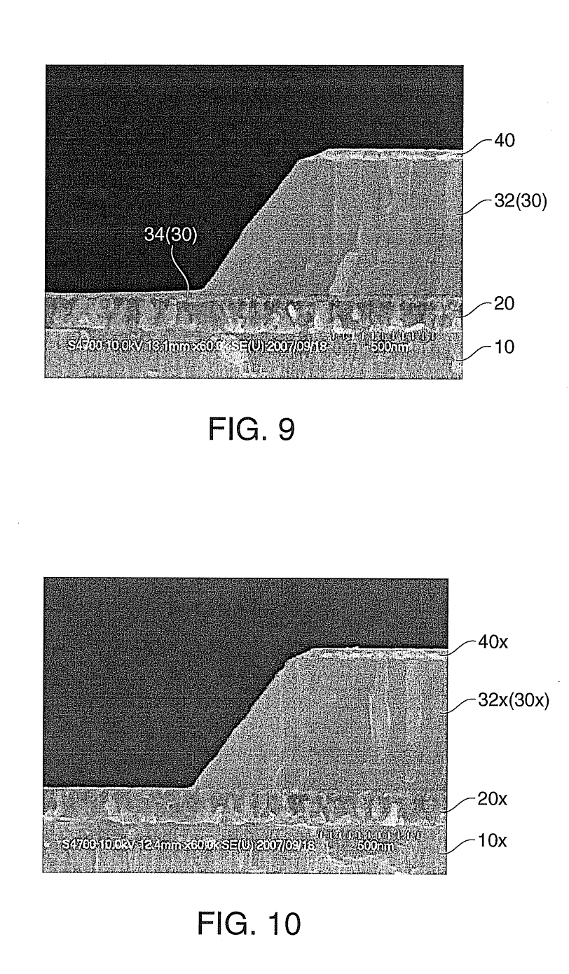

FIG. 9 is a SEM photograph of a cross section of the piezoelectric element 100 of the embodiment example formed by the method described above. According to the result of the SEM observation, it was confirmed that the piezoelectric element 100 of the embodiment example had, above the substrate 10, the lower electrode 20, the first portion 32, the second portion 34 and the upper electrode 40. It was confirmed that the second portion 34 was in a tapered shape extending outside the first portion 32, and having a film thickness that becomes thinner in a direction extending away from the first portion 32.

FIG. 10 is an SEM photograph of a cross section of the piezoelectric element of the comparison example. According to the result of the SEM observation, it was confirmed that the piezoelectric element of the comparison example had, above the substrate 10x, a lower electrode 20x, a first portion 32x of a piezoelectric layer 30x, and an upper electrode 40x. It was confirmed that the lower electrode 20x was exposed on the outside the first portion 32x, and a portion corresponding to the second portion 34 of the embodiment example was not formed.

### 3.4. Leakage Current

Leakage current of the piezoelectric element 100 of the embodiment example was evaluated.

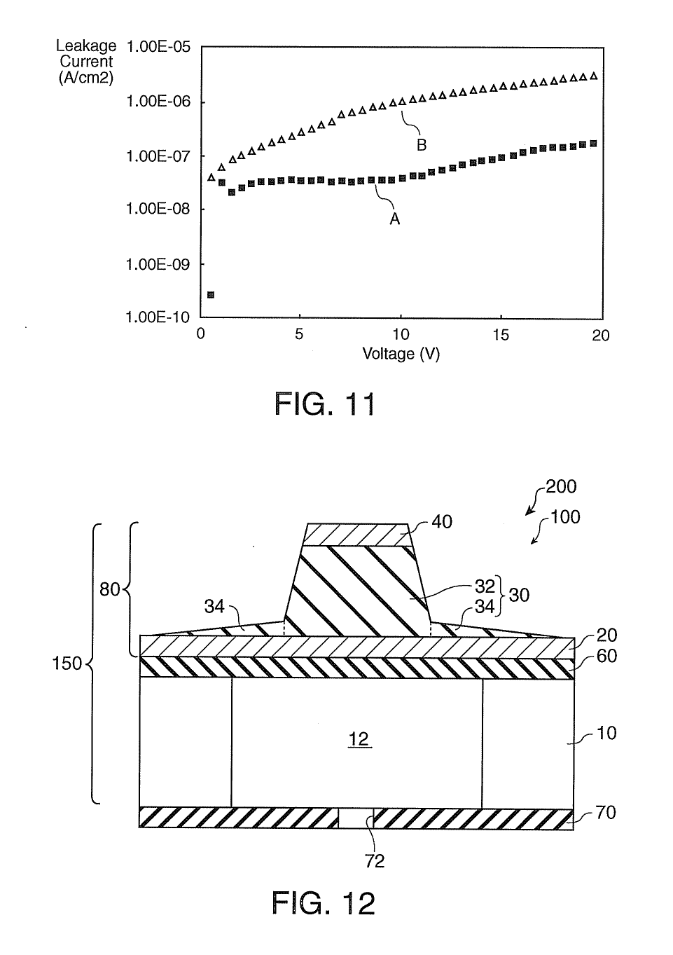

FIG. 11 shows results of measurement of leakage current of the piezoelectric element 100 of the embodiment example and the piezoelectric element of the comparison example. Mark A indicates the measurement result of the piezoelectric element 100 of the embodiment example, and mark B indicates the measurement result of the piezoelectric element of the comparison example. According to the measurement result, it was confirmed that the piezoelectric element 100 of the embodiment example had fewer leakage current at every applied voltages than that of the piezoelectric element of the comparison example. By this result, it was confirmed that the piezoelectric element 100 of the embodiment example can reduce leakage current as a result of having the second portion 34.

### 4. Piezoelectric Actuator and Liquid Jet Head

Next, a liquid jet head that has the piezoelectric element described above functioning as an actuator shall be described.

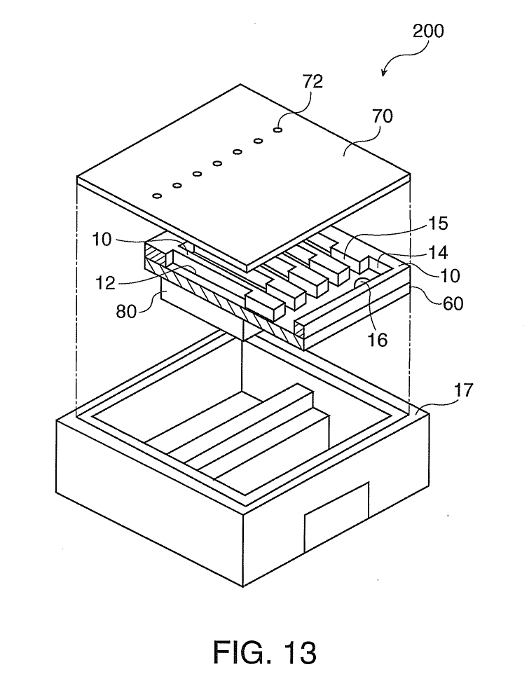

FIG. 12 is a schematic cross-sectional view of a major part of a liquid jet head 200 in accordance with an embodiment of the invention. FIG. 13 schematically shows an exploded perspective view of the liquid jet head 200 in accordance with the embodiment. It is noted that FIG. 13 shows the liquid jet head 200 upside down in an inverted state with respect to the state in normal use.

The liquid jet head 200 includes, as shown in FIG. 12, a nozzle plate 70, a pressure chamber 12, and a piezoelectric actuator 150. The piezoelectric actuator 150 includes a vibration plate 60, and a piezoelectric element 100. The liquid jet head 200 further includes a housing 17, as shown in FIG. 13. It is noted that, in FIG. 13, the illustration of a laminate 80 is simplified for the sake of convenience.

The nozzle plate 70 has nozzle apertures 72 communicating with pressure chambers 12. Ink is ejected through the nozzle apertures 72. The nozzle plate 70 is formed from, for example, a rolled plate of stainless steel (SUS). The nozzle plate 70 is affixed to a lower side (an upper side in the illustration of FIG. 13) of the substrate 10 in the state in which it is normally used. The housing 17 can store the nozzle plate 70 and the piezoelectric elements 100. The housing 17 may be formed with, for example, any one of various resin materials or any one of various metal materials.

The substrate 10 divides the space between the nozzle plate 70 and the vibration plate 60, thereby defining a reservoir (liquid reserving section) 14, supply ports 15 and pressure chambers 12. The vibration plate 60 is provided with a through-hole 16 that penetrates the vibration plate 60 in its thickness direction. The reservoir 14 temporarily stores ink that is supplied from outside (for example, from an ink cartridge) through the through-hole 16. Ink is supplied to each of the pressure chambers 12 from the reservoir 14 through each of the corresponding supply ports 15.

The pressure chambers 12 are formed in the substrate 10. The pressure chamber 12 is capable of changing its volume by deformation of the vibration plate 60. The volume change causes ink to be ejected through the nozzle aperture 72.

The vibration plate 60 is formed on the substrate 10. The vibration plate 60 can be displaced by operation of the piezoelectric element 100. The vibration plate 60 may be formed from, for example, two layers of silicon oxide and zirconium oxide.

The laminate 80 includes the lower electrode 20, the piezoelectric layer 30 and the upper electrode 40. The laminate 80 is electrically connected to a piezoelectric element driving circuit (not shown), and is capable of operating (vibrating, deforming) based on signals provided by the piezoelectric element driving circuit. The vibration plate 60 deforms by deformation of the laminate 80, and can instantaneously increase the inner pressure of the pressure chamber 12.

The piezoelectric actuator 150 and the liquid jet head 200 in accordance with the present embodiment have, for example, the following characteristics.

The piezoelectric element 100 in accordance with the present embodiment can suppress deterioration of its characteristics. As a result, the piezoelectric actuator 150 and the liquid jet head 200 that can suppress their characteristics can be provided.

The aforementioned example is described with reference to the case where the liquid jet head 200 is an ink jet type recording head. However, the liquid jet head in accordance with the invention can also be used as, for example, a color material jet head used for manufacturing color filters for liquid crystal displays and the like, an electrode material jet head used for forming electrodes for organic EL displays, FED (Field Emission Displays) and the like, and a bioorganic material jet head used for manufacturing bio-chips.

Also, for example, the piezoelectric element in accordance with the embodiment of the invention described above is applicable to devices having a capacitor structure, such as, for example, ferroelectric memories (FeRAM) and the like.

Embodiments of the invention are described above in detail. However, those having ordinary skill in the art should readily understand that many modifications can be made without departing in substance from the new matters and effects of the invention. Accordingly, all of those modified examples are deemed to be included in the scope of the invention.

What is claimed is:

1. A piezoelectric element comprising:
a substrate;
a lower electrode formed above the substrate;
a piezoelectric layer formed above the lower electrode; and
an upper electrode formed above and at least in a portion of the piezoelectric layer,
wherein the piezoelectric layer has a first portion formed between the lower electrode and the upper electrode and a second portion formed outside and continuous with the first portion, the second portion covering at least a portion of the lower electrode, and having a film thickness that is thinner than a film thickness of the first portion.

2. A piezoelectric element according to claim 1, wherein the second portion may be in a tapered shape in which the film thickness becomes thinner in a direction extending away from the first portion.

3. A piezoelectric element according to claim 1, wherein the second portion may have a maximum film thickness that is 1/10 or less of the film thickness of the first portion.

4. A piezoelectric element according to claim 1, wherein the lower electrode is a common electrode, and at least a portion of the lower electrode is exposed.

5. A piezoelectric element according to claim 1, wherein the lower electrode is a common electrode, and covered by the second portion.

6. A method for manufacturing a piezoelectric element, the method comprising the steps of:
forming a lower electrode above a substrate;
forming a piezoelectric layer above the lower electrode;
forming an upper electrode above the piezoelectric layer; and
patterning the piezoelectric layer and the upper electrode,
wherein the step of patterning is conducted by dry etching such that the piezoelectric layer has a first portion formed between the lower electrode and the upper electrode and a second portion formed outside and continuous with the first portion, and the dry etching is stopped such that the second portion covers at least a portion of the lower electrode and the second portion is formed to have a film thickness thinner than the first portion.

7. A method for manufacturing a piezoelectric element, the method comprising the steps of:
forming a lower electrode above a substrate;
forming a piezoelectric layer above the lower electrode;
forming an upper electrode above the piezoelectric layer; and
patterning the piezoelectric layer and the upper electrode,
wherein the step of patterning includes the step of
forming, by dry etching with low ion rectilinear propagation, a first portion of the piezoelectric layer between the lower electrode and the upper electrode, and forming a deposit layer in at least a portion of a side surface of the first portion;
removing the deposit layer and forming a second portion of the piezoelectric layer outside and continuous with the first portion by dry etching with high ion rectilinear propagation; and
stopping the dry etching such that the second portion covers at least a portion of the lower electrode and the second portion is formed to have a film thickness thinner than the first portion.

8. A piezoelectric actuator comprising: the piezoelectric element recited in claim 1; and a vibration plate that is formed above the substrate and is deformed by the piezoelectric element.

9. A liquid jet head comprising: the piezoelectric actuator recited in claim 8; a pressure chamber formed in the substrate; and a nozzle plate that is formed below the substrate and has a nozzle aperture communicating with the pressure chamber.
